(19) United States
(12) Patent Application Publication
(10) Pub. No.: US 2010/0328589 A1
(43) Pub. Date: Dec. 30, 2010

(54) THIN RESIN FILM AND PRODUCTION METHOD THEREOF, AND COLOR FILTER FOR LIQUID CRYSTAL DISPLAY AND PRODUCTION METHOD THEREOF

(75) Inventors: Wakahiko Kaneko, Minato-ku (JP); Koreshige Ito, Fujinomiya-shi (JP)

Correspondence Address: SUGHRUE MION, PLLC, 2100 PENNSYLVANIA AVENUE, N.W., SUITE 800, WASHINGTON, DC, 20037, US

(73) Assignee: Fujifilm Corporation, Minato-ku (JP)

(21) Appl. No.: 12/677,230

(22) PCT Filed: Sep. 8, 2008
(86) PCT No.: PCT/JP2008/066497

§ 371 Date: May 6, 2010

(30) Foreign Application Priority Data
Sep. 10, 2007 (JP) 2007-234783

(51) Int. Cl. G02F 1/1333; B32B 3/02; B32B 38/00; G03F 7/20

(52) U.S. Cl. 349/110; 428/157; 156/273.3; 430/325

(57) ABSTRACT

A black matrix (10) is formed on a transparent substrate (3), and micro color filters (12) are formed to partially overlap on the black matrix (10). The thickness of the black matrix (10) is gradually increased from an opening rim (10a) thereof to a plane portion (10b) thereof. The plane portion (10b) has substantially uniform thickness. A cross-sectional line of the thickness increasing portion of the black matrix (10) has convex curve portions P1 and P3, and a concave curve portion P2. The thickness of the black matrix (10) is controlled such that the cross-sectional line of the thickness increasing portion is kept under a tangent line contacting with both the convex curve portions P1 and P3.

### TECHNICAL FIELD

The present invention relates to a thin resin film characterized by a cross section of its thickness increasing portion, where a thickness thereof gradually increases. The present invention particularly relates to a thin resin film whose thickness increasing portion is partially overlapped by another thin resin film and production method thereof, and a color filter for liquid crystal display and production method thereof.

### BACKGROUND ART

A color filter for liquid crystal display has micro color filters each of which transmits light of only a selected color such as green, blue or red, or selected one of other colors added as necessary such as yellow or the like. The micro color filters are arranged on a transparent substrate in matrix or in an offset pattern. The micro color filters can be formed by photolithography using a color resist, staining method or printing method, or inkjet method.

Before forming the micro color filters, a black matrix with light-shielding properties is formed on the transparent substrate. The black matrix has a grid pattern that corresponds to pixel arrangement of a liquid crystal cell. Each open area of grid lines of the black matrix surrounds an outer periphery of each micro color filter. Owing to this, when displaying color images, color mixing between the adjacent pixels is prevented and contrast of the image is enhanced. The black matrix can be formed by vacuum-deposition of a thin metal layer having excellent light-shielding properties, such as chrome, on the transparent substrate. However, the black matrix made of resin is widely used in view of requirement for cost reduction and enlargement of liquid crystal display element, as disclosed in Japanese Patent Publication No. 3228139 and Japanese Patent Laid-Open Publication No. 2003-161826.

Each micro color filter is formed to close the individual open area of the grid lines. At this time, the micro color filter is formed such that its periphery overlaps on the grid line so as not to make any clearance between the grid line and the filter periphery because the clearance may leak lights. The micro color filters may be made of, for example, synthetic resin materials to which pigments for coloring are added, and formed by photolithography like the black matrix. When the micro color filters are formed by photolithography, the overlapping periphery of each micro color filter may be bulged if a cross section of a rim of the grid line is formed too steep with respect to the transparent substrate surface. This reduces planarity of the color filter. As disclosed in the above publications, an orientation film and a transparent electrode film are further formed on the color filter. When the color filter has practically intolerable unevenness in thickness, a transparent layer needs to be formed thereon to compensate the unevenness and the surface thereof is grinded to be smooth before forming the orientation film and the transparent electrode film. Such procedures cause cost increase.

To deal with such problem, in both Japanese Patent Publication No. 3228139 and Japanese Patent Laid-Open Publication No. 2003-161826, the cross section of the grid line rim of the black matrix is formed at a low angle with respect to the transparent substrate surface. For this configuration, the overlapping portion of the black matrix and the micro color filter is prevented from being extremely bulged. Moreover, Japanese Patent Laid-Open Publication No. 2003-161826 discloses that the formation of the cross section of the grid line rim of the black matrix at a low angle like 20° to 55° with respect to the transparent substrate surface is effective to prevent the occurrence of the unevenness at the overlapping portion of the black matrix and the micro color filter especially when the micro color filters are formed by the inkjet method.

When the cross section of the grid line rim, which defines the open area of the black matrix, is formed at a low angle with respect to the transparent substrate surface, width of the overlapping portion of the black matrix and the micro color filter can be increased. However, for this configuration, the thickness of layers becomes thinner as closer to the grid line rim, which decreases the light-shielding properties. Accordingly, light may leak around the periphery of the micro color filter in the case where the overlapping amount of the micro color filter is insufficient, which may result in decrease of contrast of the color image. It is therefore necessary to ensure that the periphery of the micro color filter sufficiently overlaps on the grid line of the black matrix so as not to cause the light leakage, while preventing the periphery of the micro color filter from being excessively bulged on the rim of the grid line. Furthermore, when the thickness of layers around the grid line rim is too thin, the overlapping portion may be peeled off from the transparent substrate after losing the adhesion thereto or chipped off during development processing. As a result, there arise problems in production efficiency and production yield.

Such problems may arise not only when partially overlapping the micro color filters on the formerly formed black matrix, but also when forming the black matrix after the formation of the micro color filters. In this case, the micro color filters of respective colors are sequentially formed at a regular interval, and the black matrix is formed to fill the gap between the micro color filters. Therefore, when thin resin films of different types are layered by partially overlapping with one another, the overlapping portion is required to be as flat as possible, and whole part of each thin film needs to be firmly adhered to the substrate or the lower layer.

In view of the foregoing, an object of the present invention is to improve a cross-sectional shape of a first thin resin film layer when the first thin film layer is formed in a predetermined pattern on a substrate, such as a transparent substrate, and a second thin film layer is formed to partially overlap on the first thin film layer. At this time, an overlapping portion of the first and second thin film layers should not be excessively bulged and a thickness increasing portion of the first thin film layer should be firmly adhered to the substrate.

Another object of the present invention is to provide a production method of such thin resin film layer.

To produce a color filter for liquid crystal display device, a black matrix as the first thin film layer is formed on the transparent substrate. Micro color filters as the second thin film layer are formed to partially overlap on the black matrix. The present invention is effectively applied to the black matrix as well.

### DISCLOSURE OF INVENTION

In order to achieve the above and other objects, a thin resin film of the present invention is formed in a predetermined flat pattern on a substrate. A thickness of the thin resin film gradually increases in a thickness increasing portion from an edge toward a plane portion of the thin resin film. The edge is a boundary between the flat pattern and the substrate. The plane portion is where substantially uniform thickness is achieved. A cross-sectional line of the thickness increasing portion includes a first curve portion that becomes convex at the boundary with the edge and a second curve portion that becomes convex at the boundary with the plane portion. The cross-sectional line between the first and second curve portions is kept under a tangent line contacting with both the first and second curve portions. The cross-sectional line may include at least two inflection points. Moreover, the cross-sectional line may include a straight line portion that is substantially parallel to the substrate, or two kinds of diagonal lines with different inclination angles. Any of the above configurations are effective in applying the present invention.

A production method of the above-described thin resin film according to the present invention includes the following steps. In a coating step, the substrate is coated with a resin material having light-hardening properties with substantially uniform thickness. The resin material composes the thin resin film. In a pre-baking step, the resin material is pre-baked such that an organic solvent contained in the resin material is remained in a lower layer side of the resin material. The lower layer side is in contact with the substrate. In a pattern exposure step, a pattern exposure is performed to the resin material from an outer surface side thereof for light-hardening the resin material to a predetermined depth. A pattern of the exposure corresponds to the flat pattern. In a developing step, the resin material is developed for leaving the thin resin film having the flat pattern on the substrate. At the same time, an undercut portion is formed between the thin resin film and the substrate. The undercut portion recesses inwardly from the edge toward the plane portion. In a softening step, a part of the thin resin film residing above the undercut portion is softened to close the undercut portion such that a cross-sectional line between the edge and the plane portion includes a convex first curve portion and a convex second curve portion. The cross-sectional line between the first and second curve portions is kept under a tangent line contacting with both the first and second curve portions. The first curve portion is adjacent to the edge and the second curve portion is adjacent to the plane portion. The present invention is effectively applied with ease when the above-described steps are performed in this order.

A black matrix of a color filter for liquid crystal display is a concrete example of the thin resin film of the present invention. In this case, a cross-sectional line of the thickness increasing portion of the black matrix, that is, the part where the micro color filter is layered, includes at least two inflection points, and further includes a straight line portion that is substantially parallel to the substrate surface, or two kinds of diagonal lines with different inclination angles. A production method of the color filter includes the following steps. In a coating step, a surface of the transparent substrate is coated with a resin material having light-hardening properties with substantially uniform thickness. The resin material composes the black matrix. In a pre-baking step, the resin material is pre-baked such that an organic solvent contained in the resin material is remained in a lower layer side of the resin material. The lower layer side is in contact with the transparent substrate. In a pattern exposure step, a pattern exposure is performed to the resin material from an outer surface side thereof for light-hardening the resin material to a predetermined depth. A pattern of the exposure corresponds to a grid pattern of the black matrix. In a developing step, unexposed portions of the resin material is removed by development processing for leaving the black matrix having the grid pattern on the transparent substrate. At the same time, an undercut portion is formed between the black matrix and the transparent substrate. The undercut portion recesses inwardly from each open area of the black matrix. In a softening step, a part of the black matrix residing above the undercut portion is softened to close the undercut portion such that a cross-sectional line at each softened part includes two convex curve portions. The cross-sectional line between the curve portions is kept under a tangent line contacting with both the curve portions. In a layering step, the micro color filters are sequentially layered color by color such that the open areas of the solidified black matrix are closed and the softened parts are covered. The above-described steps are performed in this order.

In the above production method, j-line and k-line are included to lights from a light source for the pattern exposure. In addition, heat energy for the pre-baking and exposure energy for the pattern exposure are adjusted to control the amount of the undercut. These are effective in obtaining particular operational effects of the present invention.

According to the present invention, the cross-sectional shape near each open area of the black matrix of the color filter for liquid crystal display is improved. Owing to this, the adhesion of the black matrix near the rim of each open area to the transparent substrate will not be lost nor causing the excessive unevenness in thickness when the micro color filters are layered to overlap on the rims of the open areas of the black matrix. When the present invention is applied, not only to the black matrix of the color filter for liquid crystal display, but also in forming a first thin film layer that is partially overlapped by a second thin film layer on the substrate, the adhesion of the thickness increasing portion of the first thin film layer to the substrate can be firmly assured, and the occurrence of the excessive unevenness in thickness at the overlapping portion of the thin film layers is prevented.

### BRIEF DESCRIPTION OF DRAWINGS

FIG. 1 is a partially enlarged sectional view of a color filter for liquid crystal display;

FIGS. 2A, 2B and 2C are explanatory views showing production processes of a black matrix;

FIG. 3 is a partially enlarged sectional view showing a boundary between the black matrix and a micro color filter;

FIG. 4 a schematic view of an undercut portion formed through a thin layer material;

FIGS. 5A, 5B, 5C and 5D are schematic sectional views showing examples of cross-sectional lines at a thickness increasing portion of the black matrix; and

FIG. 6 is a schematic block diagram of a liquid crystal display element.

### BEST MODE FOR CARRYING OUT THE INVENTION

In FIG. 6, transparent substrates 2 and 3 as supports are made of an optical glass. On an outer surface of the substrate 2, a polarizing plate 4 as a polarizer is formed, and on an outer surface of the substrate 3, a polarizing plate 5 as an analyzer is formed. On an inner surface of the substrate 2, which is opposite to the outer surface, transparent electrodes 8 are formed such that they are arranged in a regular pattern, and an orientation film 9 is formed to cover the transparent electrodes 8. The transparent electrodes 8 are arranged in matrix and each of them is used to drive a liquid crystal molecule of a liquid crystal layer 6 by pixel unit.

On an inner surface of the substrate 3, which is opposite to the outer surface, a black matrix 10 and micro color filters 12 are formed. A transparent electrode 13 is formed to cover the black matrix 10 and the micro color filters 12, and an orientation film 14 is formed over the transparent electrode 13. The black matrix 10 has a grid pattern such that parts facing the transparent electrodes 8 are formed to be openings and the micro color filters 12 are formed to cover the respective openings. There are three kinds of micro color filters 12: green light transmission filter, blue light transmission filter and red light transmission filter, and one of these filters 12 covers each opening.

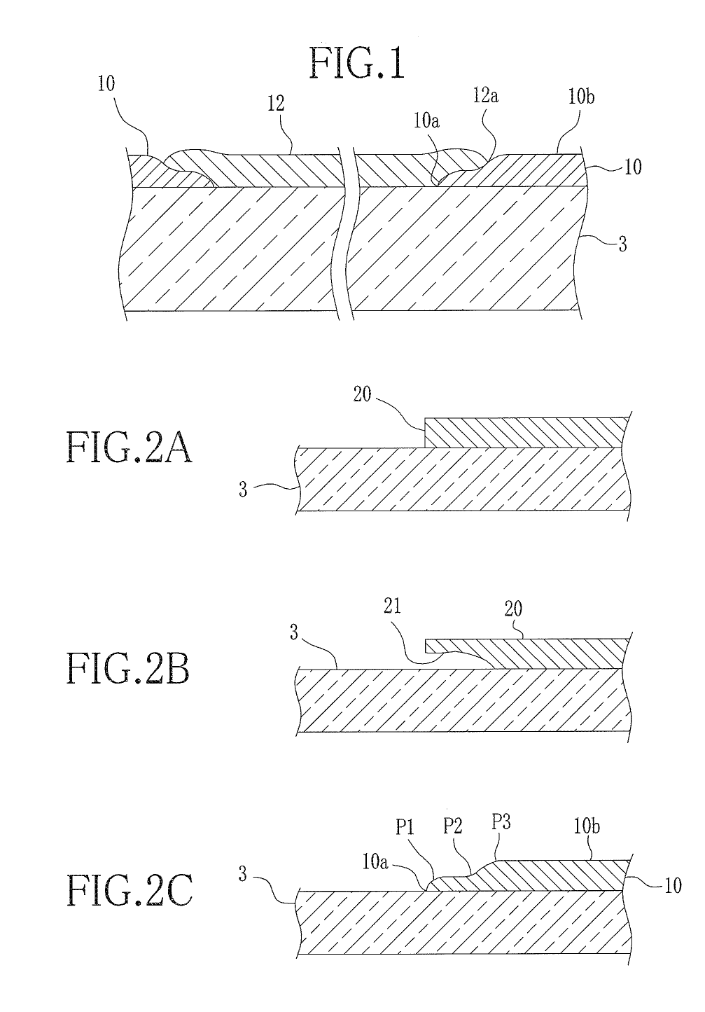

In FIG. 6, although the boundary between the black matrix 10 and the micro color filter 12 is shown linearly, the micro color filter 12 partially overlaps the black matrix 10 as shown in FIG. 1. FIG. 1 shows one pixel of a color filter for liquid crystal display in which the black matrix 10 is formed on the transparent substrate 3 and the micro color filter 12 is further formed on the black matrix 10. Since the micro color filter 12 partially overlaps the black matrix 10, there is no clearance between an opening rim 10a of the black matrix 10 and a periphery 12a of the micro color filter 12.

To partially overlap the micro color filter 12 on the black matrix 10 while preventing the micro color filter 12 from bulging, the black matrix 10 has a cross-sectional line such that the thickness of the black matrix 10 gradually increases from the opening rim 10a to a plane portion 10b. The opening rim 10a defines the opening opposite to the transparent electrode 8. The plane portion 10b has substantially uniform thickness. To obtain such cross-sectional line, the black matrix 10 is made of synthetic resin material and applied photolithography to be formed into the grid pattern. Hereinafter, the part of the black matrix 10 where its thickness gradually increases is referred to as “thickness increasing portion”.

A thin film material composing the black matrix 10 is, for example, an alkali soluble synthetic resin to which black pigment such as carbon black is mixed. The black pigment is added as a light-shielding agent. The synthetic resin has light-hardening properties. Moreover, an organic solvent is added to this synthetic resin for providing fluidity. After applying cleaning processing to the transparent substrate 3, the thin film material is uniformly coated on the surface of the transparent substrate 3 with approximately uniform thickness within the range of 1.0 μm to 2.0 μm using a slit coater. Inkjet method and screen printing method are also applicable as the coating method. After coating the thin film material, vacuum-drying processing is applied for evaporating part of the excessive organic solvent.

Next, pre-bake processing is performed to further evaporate the organic solvent. At this time, a pre-bake temperature is controlled low so that the organic solvent will not be completely evaporated. The pre-bake processing is generally performed for the purpose of making the thin film material adhere to the substrate. In the present invention, however, the pre-bake processing is performed to sufficiently evaporate the organic solvent from the outer surface side while leaving part of the organic solvent on the substrate side, and therefore keeping the pre-bake temperature low (for example, 70° C. to 90° C.). The content of the remaining organic solvent in the thin film material on the substrate side can be adjusted by controlling the pre-bake temperature and pre-bake time.

Next, a pattern exposure is performed to form the grid pattern of the black matrix 10. The pattern exposure is performed from the outer surface side of the thin film material using an exposure mask having a grid light-transmission pattern. For this pattern exposure, a high-pressure mercury lamp is used as a light source, and not only the spectral lines generally used for the pattern exposure, such as g-line (436 nm), i-line (365 nm) and h-line (405 nm), but also other spectral lines normally filtered, such as j-line (313 nm) and k-line (393 nm) are used. The pattern exposure is generally performed with light energy of 50 mJ/cm². In the pattern exposure according to the present invention, however, the light energy at relatively high intensity of 70 mJ/cm² to 100 mJ/cm² is applied to the thin film material to harden it. Although the thin film material has high light-shielding properties due to the mixture of the black pigment, such pattern exposure processing applies the light energy that can reach near the substrate side of the thin film material. Owing to this, the thin film material can sufficiently be hardened in its depth direction. However, the organic solvent remaining in the substrate side of the thin film material may hinder the hardening. When intensities of j-line and k-line are too high, only the outermost surface of the thin film material is excessively hardened and forms a thin skin-like brittle layer, which is not preferable. Therefore, in order to harden the thin film material at practically appropriate level, it is desirable to control the intensities of j-line and k-line within the range of 10% to 50% with respect to the intensity of i-line by using a neutral density filter and the like.

After the pattern exposure processing, development processing using alkali aqueous solution is performed. Parts not exposed in the pattern exposure processing are dissolved into the alkali aqueous solution. The development processing is performed by shower-washing the thin film material with the alkali aqueous solution. The processing degree can be controlled by adjusting development processing time, shower pressure, supplying amount of the alkali aqueous solution per unit time, and environmental temperature. For example, the following conditions are preferable: the development processing time is set relatively long like 70 sec to 100 sec, the shower pressure is set relatively low like 0.05 MPa to 0.15 MPa, and the environmental temperature is set low as 23° C. to 27° C.

FIG. 2A shows a thin film material layer 20 after the pattern exposure processing. When the development processing is performed under the above-described conditions, an undercut portion 21 that recesses inwardly from an edge of the thin film material layer 20 is formed as shown in FIG. 2B. Height and depth of the undercut portion 21 are controlled not only by changing the development processing conditions, but also by changing the conditions and settings of the pre-bake processing and the pattern exposure processing. Since the organic solvent remains in the substrate side of the thin film material by the pre-bake processing, the undercut portion 21 can be formed with leaving little residue even when the development processing is performed with a low shower pressure. Although FIG. 2 shows only one undercut portion 21, the undercut portion 21 is formed almost simultaneously on each rim of the rectangular openings of the black matrix 10 at similar extent.

Next, post-bake processing is performed. The post-bake processing is a heating processing to sufficiently harden the thin film material by evaporating the organic solvent remaining therein. The post-bake processing is performed at a temperature of 200° C. to 240° C. for 20 min to 60 min. Owing to this post-bake processing, the shape of the thin film material protruding like a flange above the undercut portion 21 is changed by heat and this portion adheres to the transparent substrate 3 as shown in FIG. 2C. As a result, the black matrix having the cross-sectional line shown in FIG. 1 can be obtained.

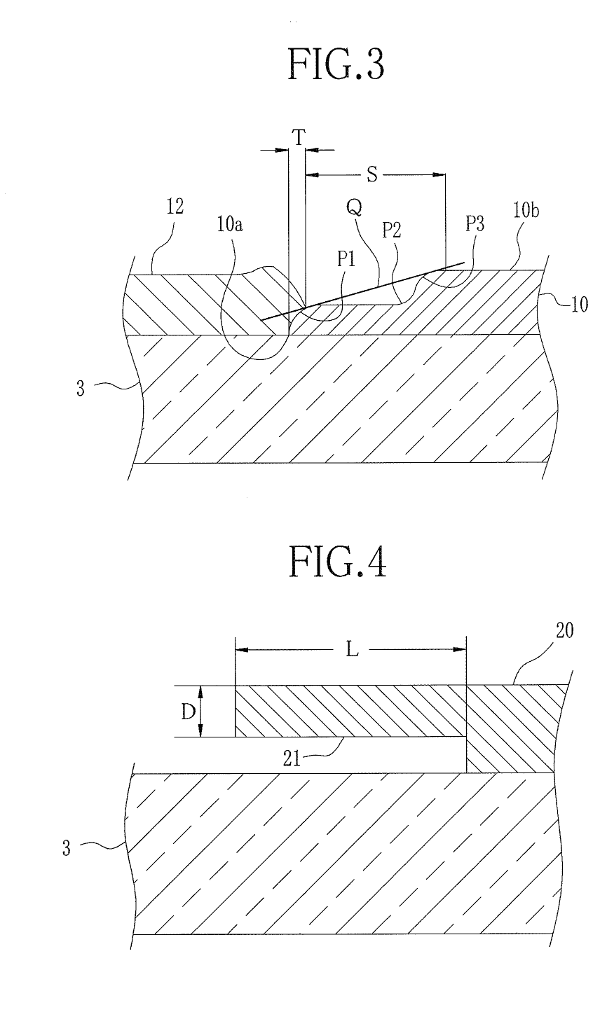

As shown in FIG. 2C, the thickness of the black matrix 10 gradually increases from the opening rim 10a to the plane portion 10b. Moreover, the cross-sectional line of the black matrix 10 has a convex curve portion P1, a concave curve portion P2 and a convex curve portion P3, and includes at least two inflection points at the opposite ends of the concave curve portion P2. Between the convex curve portion P1 and the concave curve portion P2, there is a straight line portion where the thickness is substantially uniform. This straight line portion is advantageous in increasing an overlapping latitude S (see FIG. 3). The overlapping latitude S is a width of the black matrix 10 which can be overlapped by the micro color filter 12 while assuring a minimum overlapping width T and preventing the overlapping portion of the micro color filter 12 from bulging extremely. The minimum overlapping width T is a width not forming clearance between the opening rim 10a and the micro color filter 12.

To increase the overlapping latitude S, the cross-sectional line between the opening rim 10a and the plane portion 10b where the thickness of the black matrix 10 gradually increases needs to be kept under a tangent line Q. After the post-bake processing, the shape of the black matrix 10 is changed by heat, and the convex curve portion P1 is formed near the opening rim 10a and the convex curve portion P3 is formed near the boundary with the plane portion 10b. The tangent line Q contacts with both the convex curve portions P1 and P3. If the cross-sectional line between the opening rim 10a and the plane portion 10b is kept under the tangent line Q, the overlapping latitude S can be kept wide when the micro color filter 12 is layered.

To form such particular shape of the cross-sectional line of the thickness increasing portion of the black matrix 10, the undercut portion 21 is formed after the development processing and before the post-bake processing, as shown in FIG. 4. The undercut portion 21 is characterized by its depth L and height D. The height D is the thickness of the thin film material protruding like a flange above the undercut portion 21. Amounts of the characteristics L and D are controlled by changing conditions of the pre-bake processing, the pattern exposure processing, and the development processing.

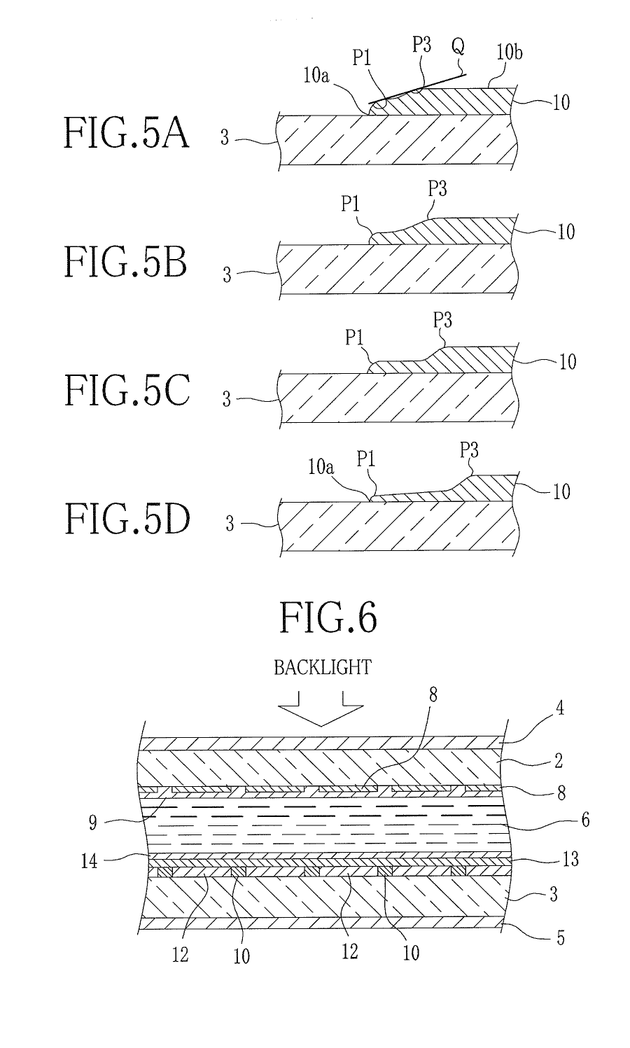

Examples of other types of cross-sectional lines obtained by changing the amounts of the characteristics L and D are shown in FIGS. 5A to 5D. In any cases, the shape of the black matrix 10 is changed by heat in the post-bake processing, and the convex curve portions P1 and P3, which are the inflection points, are formed between the opening rim 10a and the plane portion 10b where the thickness of the black matrix 10 gradually increases. Between these inflection points P1 and P3, the cross-sectional line is kept so as not to go beyond the tangent line Q.

FIG. 5A shows a case where the depth L is made small and the thickness D is made large. Such adjustment of the amounts of the characteristics of the undercut portion 21 can be made by enhancing the levels of the post-bake processing and the pattern exposure processing, and by lowering the level of the development processing. When the level of the post-bake processing is enhanced, evaporation amount of the organic solvent is increased. The enhancement in the level of the pattern exposure processing makes the thickness D large. The lowering in the level of the development processing makes the depth L small. Owing to this, the formed undercut portion 21 has small height and depth, and therefore a curvature radius of the convex curve portion P1 becomes large and a curvature radius of the convex curve portion P3 becomes small. Accordingly, the thickness increasing portion of the black matrix 10 becomes short. However, the cross-sectional line between the convex curve portions P1 and P3 is kept under the tangent line Q, and therefore practically enough overlapping latitude S can be obtained when the micro color filter 12 is layered.

FIG. 5B shows a case where the depth L is made larger and the thickness D is made smaller compared to the example shown in FIG. 5A. The cross-sectional line of the thickness increasing portion shown in FIG. 5B has a standard form. FIG. 5C shows a case where the depth L is made even larger and the thickness D is made even smaller compared to the example of FIG. 5B, and FIG. 5D shows a case where the depth L is made even larger and the thickness D is made even smaller compared to the example of FIG. 5C. Although the example of FIG. 5D provides the most advantageous overlapping latitude S among the above, the curvature radius of the convex curve portion P1 becomes so small that the thickness around the convex curve portion P1 becomes too thin. As a result, the light-shielding properties necessary for the black matrix 10 may not be assured. Therefore, the thickness D needs to be adjusted such that the thickness of the black matrix 10 with necessary light-shielding properties is assured.

In the thickness increasing portion of the example shown in FIG. 5D, there are a low-pitched straight line portion extending from the convex curve portion P1 and a high-pitched straight line portion extending from the convex curve portion P3 towards the opening rim 10a. Even when the cross-sectional line between the convex curve portions P1 and P3 includes two kinds of diagonal lines of different inclination angles, similar effects can be obtained.

According to the present invention, the depth L and the thickness D, which are the amounts of the characteristics of the undercut portion 21 shown in FIG. 4, can be appropriately controlled by adjusting various conditions of the processing. Owing to this, the shape of the thickness increasing portion of the black matrix 10 can be changed according to the accuracy of layering the micro color filter 12. That is, the form of the thickness increasing portion can appropriately be selected according whether the micro color filter 12 is layered by, for example, photolithography, inkjet method, printing method or the like. As a result, the color filter for liquid crystal display can be produced with ease, and production yield can be substantially improved.

As shown in FIG. 5D, when the thickness of the black matrix 10 is made small within the range assuring necessary light-shielding properties, the thickness increasing portion of the black matrix 10 can be made long enough to obtain sufficient overlapping latitude S. Owing to this, the overlapping accuracy for layering the micro color filter 12 by photolithography need not be controlled so strictly, which results in const reduction.

In the above description, the black matrix 10 used in the color filter for liquid crystal display is taken as an example for explaining the present invention. However, the present invention is not limited to the black matrix but also applicable to other types of thin resin films. For example, when the micro color filter is formed by photolithography, the technical difference between the micro color filter and the black matrix is only in that the pigments are mixed to the synthetic resin for the purpose of coloring it or providing it with light-shielding properties. When three kinds of micro color filters are firstly formed on the transparent substrate such that they are arranged in matrix and the black matrix is formed to fill the gap between the color filters, the present invention is also applicable to the formation of the micro color filters.

1. A thin resin film formed in a predetermined flat pattern on a substrate comprising:
an edge being a boundary between said flat pattern and said substrate;
a plane portion having substantially uniform thickness; and
a thickness increasing portion between said edge and said plane portion, a thickness of said thin resin film gradually increasing in said thickness increasing portion from said edge toward said plane portion, a cross-sectional line of said thickness increasing portion including a first curve portion and a second curve portion,
said first curve portion being convex at the boundary between said thickness increasing portion and said edge,
said second curve portion being convex at the boundary between said thickness increasing portion and said plane portion,
said cross-sectional line between said first and second curve portions being kept under a tangent line contacting with both said first and second curve portions.

2. The thin resin film of claim 1, wherein said cross-sectional line includes at least two inflection points.

3. The thin resin film of claim 1, wherein said cross-sectional line includes a straight line portion substantially parallel to said substrate.

4. The thin resin film of claim 1, wherein said cross-sectional line includes two kinds of diagonal lines with different inclination angles.

5. A production method of a thin resin film formed in a predetermined flat pattern on a substrate, a thickness of said thin resin film gradually increasing from an edge toward a plane portion of said thin resin film, said edge being a boundary between said flat pattern and said substrate, said plane portion having substantially uniform thickness, said method comprising the steps of:
coating said substrate with a resin material having light-hardening properties with said substantially uniform thickness, said resin material composing said thin resin film;
pre-baking said resin material such that an organic solvent contained in said resin material is remained in a lower layer side of said resin material, said lower layer side being in contact with said substrate;
performing a pattern exposure to said resin material from an outer surface side thereof for light-hardening said resin material to a predetermined depth, a pattern of said exposure corresponding to said flat pattern;
developing said resin material for leaving said thin resin film having said flat pattern on said substrate and forming an undercut portion between said thin resin film and said substrate, said undercut portion recessing inwardly from said edge toward said plane portion; and
softening a part of said thin resin film residing above said undercut portion for closing said undercut portion such that a cross-sectional line between said edge and said plane portion includes a first curve portion being convex at the boundary with said edge and a second curve portion being convex at the boundary with said plane portion, and that said cross-sectional line between said first and second curve portions is kept under a tangent line contacting with both said first and second curve portions.

6. A color filter for liquid crystal display comprising:
a transparent substrate;
a black matrix made of a resin material formed on said transparent substrate, said resin material including a light-shielding agent; and
micro color filters layered on said black matrix so as to close open areas of said black matrix and cover rims of said open areas, wherein
a cross-sectional line of said black matrix at a portion where said micro color filters are layered includes two convex curve portions, said cross-sectional line between said convex curve portions being kept under a tangent line contacting with both said curve portions.

7. The color filter of claim 6, wherein said cross-sectional line includes a straight line portion substantially parallel to a surface of said transparent substrate.

8. The color filter of claim 6, wherein said cross-sectional line includes two kinds of diagonal lines with different inclination angles.

9. A production method of a color filter for liquid crystal display, including a transparent substrate, a black matrix made of resin formed on said transparent substrate, and micro color filters closing open areas of said black matrix, said method comprising the steps of:
coating a surface of said transparent substrate with a resin material having light-hardening properties with substantially uniform thickness, said resin material composing said black matrix;
pre-baking said resin material such that an organic solvent contained in said resin material is remained in a lower layer side of said resin material, said lower layer side being in contact with said transparent substrate;
performing a pattern exposure to said resin material from an outer surface side thereof for light-hardening said resin material to a predetermined depth, a pattern of said exposure corresponding to a grid pattern of said black matrix;
removing unexposed portions of said resin material by development processing for leaving said black matrix having said grid pattern on said transparent substrate and forming an undercut portion between said black matrix and said transparent substrate, said undercut portion recessing inwardly from each of said open area of said black matrix;
softening a part of said black matrix residing above said undercut portion for closing said undercut portion such that a cross-sectional line at each softened part includes two convex curve portions, and that said cross-sectional line between said convex curve portions is kept under a tangent line contacting with both said curve portions; and
sequentially layering said micro color filters color by color such that said open areas of said black matrix solidified are closed and said softened parts are covered.

10. The production method of claim 9, wherein j-line and k-line are included to lights from a light source for said pattern exposure.
